(19) United States
(12) Patent Application Publication
(10) Pub. No.: US 2016/0163645 A1
(43) Pub. Date: Jun. 9, 2016

(54) SEMICONDUCTOR STRUCTURE WITH BOTTOM-FREE LINER FOR TOP CONTACT

(71) Applicant: GLOBALFOUNDRIES Inc., Grand Cayman (KY)

(72) Inventors: Vimal K. KAMINENI, Mechanicville, NY (US); Ruilong XIE, Schenectady, NY (US)

(73) Assignee: GLOBALFOUNDRIES Inc., Grand Cayman, KY (US)

(21) Appl. No.: 14/563,284

(22) Filed: Dec. 8, 2014

(51) Int. Cl. H01L 23/535; H01L 21/768; H01L 23/532; H01L 23/522; H01L 23/528

(52) U.S. Cl. CPC H01L 23/535; H01L 23/5226; H01L 23/528; H01L 23/53266; H01L 23/5329; H01L 21/76802; H01L 21/76831; H01L 21/76877; H01L 21/7684

(57) ABSTRACT

A semiconductor structure includes a lined bottom contact filled with conductive material. The structure further includes a layer of dielectric material surrounding sides of the lined bottom contact, a top contact on the bottom contact, the top contact having a partial liner only along sides thereof with an absence of the liner at a bottom thereof and being filled with the conductive material, and a layer of the dielectric material surrounding sides of the partially lined top contact. Fabrication of the bottom-liner free top contact includes providing a starting structure, the structure including a lined bottom contact filled with conductive material, being surrounded by a layer of dielectric material and having a planarized top surface. The method further includes creating a top layer of dielectric material above the planarized top surface, creating a layer of liner material above the top dielectric layer, creating a top contact opening to the bottom contact, lining the top contact opening with a liner material, removing the liner at a bottom of the top contact opening, exposing the bottom contact, while preserving a portion of the liner on the top dielectric layer sufficient to allow adhesion of a subsequent conductive material, and filling the contact opening with the conductive material.

### BACKGROUND OF THE INVENTION

1. Technical Field

The present invention generally relates to contacts for semiconductor devices. More particularly, the present invention relates to bottom-free contact liners for semiconductor devices.

2. Background Information

In the fabrication of semiconductor devices, electrical connections to the various components of such devices are shrinking along with device size, making it difficult to make reliable connections. In some applications, a combination of a bottom lined contact and a top lined contact are used. While it would be desirable to remove the bottom portion of the liner for the top contact for a better connection, such an etch would also remove the liner on the top surface of the dielectric surrounding the opening for the top contact. Conductive material used to fill the top contact would inadequately adhere to the top surface.

Thus, a need continues to exist for a bottom-free top contact liner for semiconductor devices.

### SUMMARY OF THE INVENTION

The shortcomings of the prior art are overcome and additional advantages are provided through the provision, in one aspect, of a method of fabricating a bottom-liner free top contact. The method includes providing a starting structure, the structure including a lined bottom contact filled with conductive material, being surrounded by a layer of dielectric material and having a planarized top surface. The method further includes creating a top layer of dielectric material above the planarized top surface, creating a layer of liner material above the top dielectric layer, creating a top contact opening to the bottom contact, lining the top contact opening with a liner material, removing the liner at a bottom of the top contact opening, exposing the bottom contact, while preserving a portion of the liner on the top dielectric layer sufficient to allow adhesion of a subsequent conductive material, and filling the contact opening with the conductive material.

In accordance with another aspect, a semiconductor structure is provided. The structure includes at least one lined bottom contact filled with conductive material. The structure further includes a layer of dielectric material surrounding sides of the lined bottom contact, a top contact on the bottom contact, the top contact having a partial liner only along sides thereof with an absence of the liner at a bottom thereof and being filled with the conductive material, and a layer of the dielectric material surrounding sides of the partially lined top contact.

In accordance with yet another aspect, a semiconductor structure is provided. The structure includes at least one lined bottom contact filled with a conductive material and surrounded by a layer of dielectric material. The structure further includes another layer of dielectric material over the at least one region and the layer of dielectric material, a layer of contact liner material over the another layer of dielectric material, and a preserving layer above the layer of contact liner material, the preserving layer preserving the layer of contact liner material in subsequent processing.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a planarized starting semiconductor structure, the structure including a bottom contact for a semiconductor device, for example, a source and/or drain region of a semiconductor device (e.g., a transistor), or, as another example, a local interconnect, the bottom contact including a liner and filled with a conductive material, the bottom contact surrounded on the sides by a layer of dielectric material, in accordance with one or more aspects of the present invention.

FIG. 2 depicts one example of the starting structure of FIG. 1 after creation of a top layer of dielectric material over the planarized surface of the starting structure, and after creation of a relatively thick layer of liner metal (also referred to as a barrier layer), for example, titanium nitride, in accordance with one or more aspects of the present invention.

FIG. 3 depicts one example of the structure of FIG. 2 after creating an opening to the conductive material through the liner metal layer and the top dielectric layer, in accordance with one or more aspects of the present invention.

FIG. 4 depicts one example of the structure of FIG. 3 after creation of a liner metal over the structure, in accordance with one or more aspects of the present invention.

FIG. 5 depicts one example of the structure of FIG. 4 after etching horizontal surfaces of the liner metal selective to the conductive material, exposing the conductive material, in accordance with one or more aspects of the present invention.

FIG. 6 depicts one example of the structure of FIG. 5 after filling the partially lined opening with the conductive material, in accordance with one or more aspects of the present invention.

FIG. 7 depicts one example of the structure of FIG. 6 after planarizing the structure through the excess conductive material and the layer of liner metal, down to the top layer of dielectric material, in accordance with one or more aspects of the present invention.

FIG. 8 depicts another example of the structure of FIG. 1 after creation of a top layer of dielectric material thereover, creating a layer of liner metal (relatively thin compared to the liner metal layer in FIG. 2) over the top dielectric layer and a top layer of a sacrificial material, in accordance with one or more aspects of the present invention.

FIG. 9 depicts one example of the structure of FIG. 8 after creating an opening to the conductive material through the sacrificial layer, the liner metal layer and the dielectric layer, in accordance with one or more aspects of the present invention.

FIG. 10 depicts one example of the structure of FIG. 9 after creation of another layer of liner metal over the structure, in accordance with one or more aspects of the present invention.

FIG. 11 depicts one example of the structure of FIG. 10 after etching horizontal surfaces of the liner selective to the conductive material, exposing the conductive material, in accordance with one or more aspects of the present invention.

FIG. 12 depicts one example of the structure of FIG. 11 after removing the sacrificial layer, and filling the partially lined opening with the conductive material, in accordance with one or more aspects of the present invention.

FIG. 13 depicts one example of the structure of FIG. 1 after creation of a top layer of dielectric material thereover, creating a layer of liner metal (relatively thin compared to the liner metal in FIG. 2) over the top dielectric layer and a layer of the conductive material over the top liner metal layer, in accordance with one or more aspects of the present invention.

FIG. 14 depicts one example of the structure of FIG. 13 after creating an opening to the conductive material of the bottom contact through the top layer of conductive material, the top liner metal layer and the top dielectric layer, creating a liner over the structure, and etching horizontal surfaces of the liner selective to the conductive material, exposing the conductive material of the bottom contact, in accordance with one or more aspects of the present invention.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

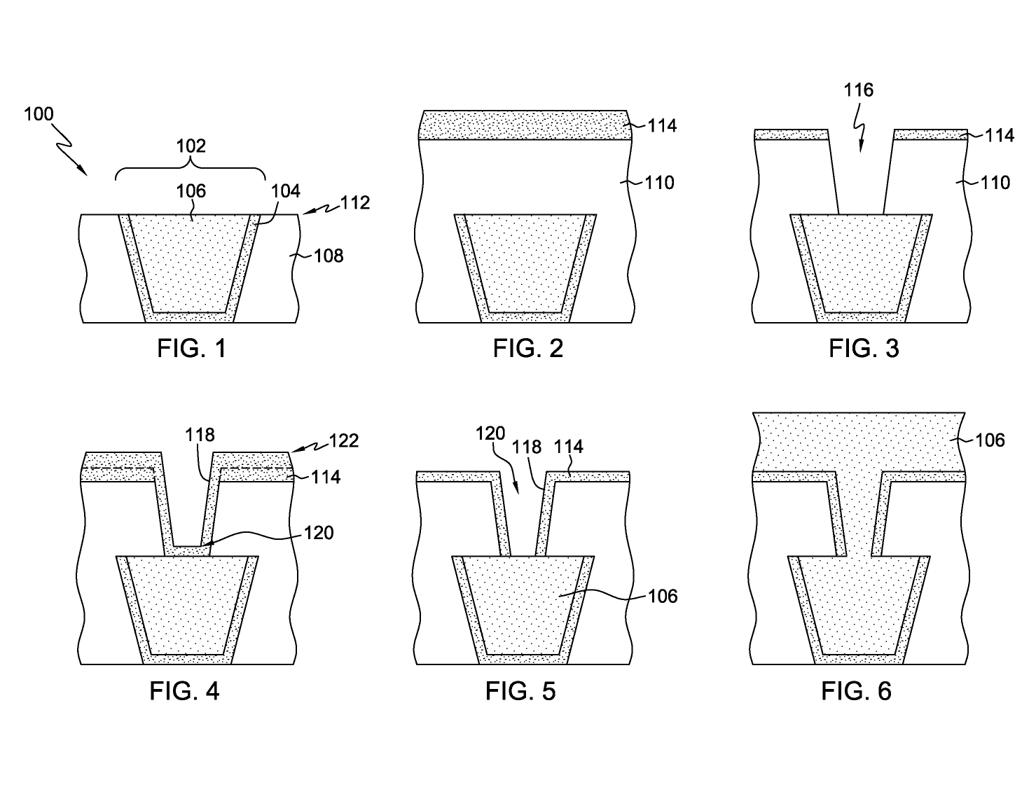

FIG. 1 is a cross-sectional view of one example of a planarized starting semiconductor structure 100, the structure including a bottom contact 102 for a semiconductor device, for example, a source and/or drain region of a semiconductor device (e.g., a transistor), or, as another example, a local interconnect, the bottom contact including a liner 104 and filled with a conductive material 106, the bottom contact surrounded on the sides by a layer 108 of dielectric material, in accordance with one or more aspects of the present invention.

The starting structure may be conventionally fabricated, for example, using known processes and techniques. However, it will be understood that the fabrication of the starting structure forms no part of the present invention. Further, although only a portion of the overall device is shown for simplicity, it will be understood that, in practice, many such structures are part of many such devices typically included on the same bulk substrate. Further, the contact structure of the invention is applied to both planar and non-planar semiconductor devices.

In one example, the dielectric material includes an oxide, for example, an inter-layer dielectric. The liner may include, for example, a metal, e.g., titanium nitride (TiN). The conductive material of the bottom contact may include, for example, tungsten.

FIG. 2 depicts one example of the starting structure of FIG. 1 after creation of a top layer 110 of the dielectric material over the planarized surface (112, FIG. 1) of the starting structure, and after creation of a relatively thick layer 114 of liner metal (also referred to as a barrier layer), for example, titanium nitride, in accordance with one or more aspects of the present invention. The liner metal serves to enhance adhesion, creates a barrier to the layers above and below, and, in some cases, may be used as a nucleation layer.

In one example, the layer 114 of liner metal may have a thickness of about 10 nm to about 30 nm. The thickness is chosen such that when the etch to remove the bottom liner is performed, enough of the liner material remains on a top surface of the top dielectric layer 110 to prevent adhesion problems when the top contact is filled with conductive material.

FIG. 3 depicts one example of the structure of FIG. 2 after creating an opening 116 to the conductive material 106 through the liner metal layer 114 and top dielectric layer 110, in accordance with one or more aspects of the present invention. In one example, creating the opening may be accomplished in a single step using, for example, a reactive ion etch process.

FIG. 4 depicts one example of the structure of FIG. 3 after creation of a liner metal 118 over the structure, in accordance with one or more aspects of the present invention. In one example, the liner includes a metal (e.g., TiN, TaN, WN or WC), and may be created, for example, using a conventional deposition process (e.g., Atomic layer deposition).

FIG. 5 depicts one example of the structure of FIG. 4 after etching horizontal surfaces (120, 122 FIG. 4) of liner metal 118 selective to conductive material 106, exposing the conductive material, in accordance with one or more aspects of the present invention. In one example, the selective etch may be accomplished using a anisotropic reactive ion etch process.

FIG. 6 depicts one example of the structure of FIG. 5 after filling the partially lined opening (120, FIG. 5) with a conductive material 106, in accordance with one or more aspects of the present invention. The conductive material may include, for example, a metal (e.g., tungsten or cobalt), and the filling may be accomplished, for example, using conventional processes and techniques.

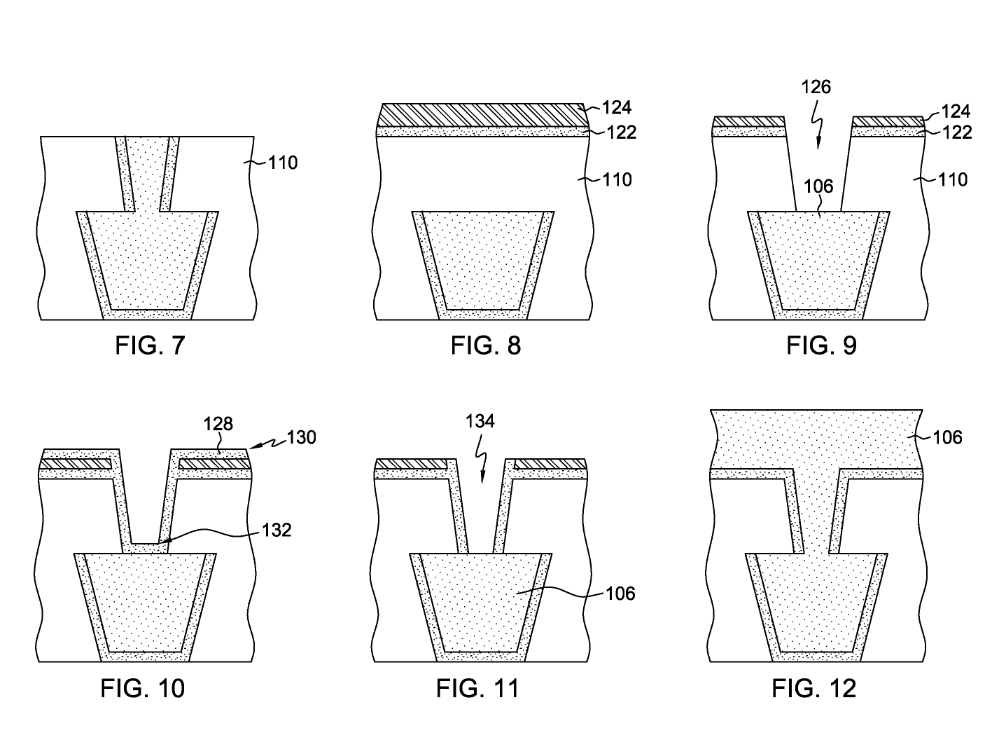

FIG. 7 depicts one example of the structure of FIG. 6 after planarizing the structure through the excess conductive material and the remainder of layer 114 of liner metal, down to the top layer 110 of dielectric material, in accordance with one or more aspects of the present invention. In one example, the planarizing may be accomplished using a conventional chemical-mechanical polish (CMP) process.

FIG. 8 depicts another example of the structure of FIG. 1 after creation of a top layer 110 of dielectric material thereover, creating a layer 122 of liner metal (relatively thin compared to liner metal 114 in FIG. 2) over the top dielectric layer and top layer 124 of sacrificial material, in accordance with one or more aspects of the present invention.

The top layer 110 of dielectric material may include, for example, an oxide (e.g., an inter-layer dielectric). Liner metal layer 122 may include, for example, titanium nitride, which may have a thickness of, for example, about 3 nm to about 5 nm. Top layer 124 of sacrificial material may include, for example, a silicon-based material, e.g., amorphous silicon, silicon nitride or silicon dioxide, and may be deposited using, for example, conventional processes and techniques.

FIG. 9 depicts one example of the structure of FIG. 8 after creating an opening 126 to the conductive material 106 through sacrificial layer 124, liner metal layer 122 and top dielectric layer 110, in accordance with one or more aspects of the present invention. In one example, creating the opening may be accomplished in a single step using, for example, a reactive ion etch process.

FIG. 10 depicts one example of the structure of FIG. 9 after creation of another layer of liner metal 128 over the structure, in accordance with one or more aspects of the present invention. In one example, the liner includes a metal layer (e.g., TiN), and may be created, for example, using a conventional deposition process.

FIG. 11 depicts one example of the structure of FIG. 10 after etching horizontal surfaces (130, 132 FIG. 10) of liner 128 selective to the conductive material 106, exposing the conductive material, in accordance with one or more aspects of the present invention. In one example, the selective etch may be accomplished using a anisotropic reactive ion etch process.

FIG. 12 depicts one example of the structure of FIG. 11 after removing sacrificial layer 124, and filling partially lined opening (134, FIG. 11) with conductive material 106, in accordance with one or more aspects of the present invention. The removal of the sacrificial layer may be accomplished, for example, using a selective wet or dry etch, the conductive material may include, for example, a metal (e.g., tungsten), and the filling may be accomplished, for example, using conventional processes and techniques.

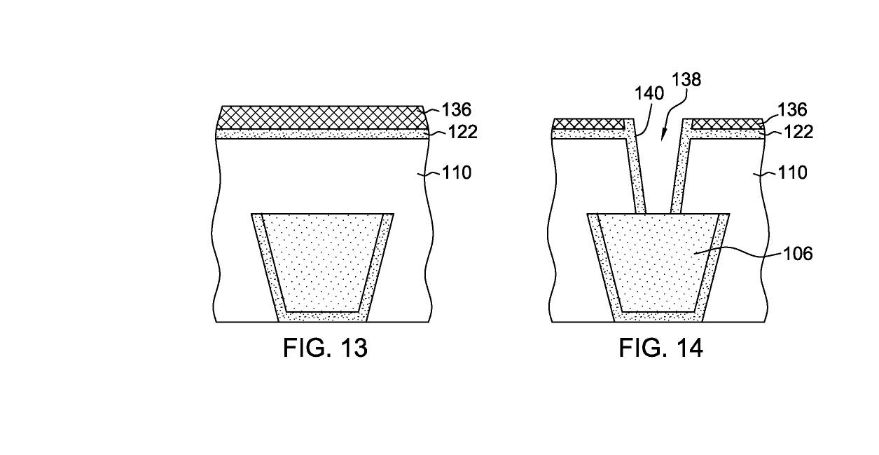

FIG. 13 depicts one example of the structure of FIG. 1 after creation of a top layer 110 of dielectric material thereover, creating a layer 122 of liner metal (relatively thin compared to liner metal layer 114 in FIG. 2) over the top dielectric layer and a layer 136 of conductive material over the top liner metal layer, in accordance with one or more aspects of the present invention.

The top layer 110 of dielectric material may include, for example, an oxide (e.g., an inter-layer dielectric). Liner metal layer 122 may include for example, titanium nitride, which may have a thickness of, for example, about 3 nm to about 5 nm. The top layer 136 of conductive material may include, for example, a metal (e.g., tungsten or cobalt), and may be created using, for example, conventional processes and techniques.

FIG. 14 depicts one example of the structure of FIG. 13 after creating an opening 138 to the conductive material 106 of the bottom contact through the top layer 136 of conductive material, the top liner metal layer 122 and the top dielectric layer 110, creating a liner 140 over the structure, and etching horizontal surfaces of the liner selective to the conductive material, exposing the conductive material of the bottom contact, in accordance with one or more aspects of the present invention.

In one example, creating the opening may be accomplished in a single step using, for example, a reactive ion etch process. In one example, the liner includes a metal layer (e.g., TiN), and may be created, for example, using a conventional deposition process. In one example, the selective etch may be accomplished using a anisotropic reactive ion etch process.

In a first aspect, disclosed above is a method of fabricating a bottom-liner free top contact. The method includes providing a starting structure, the structure including a lined bottom contact filled with conductive material, being surrounded by a layer of dielectric material and having a planarized top surface. The method further includes creating a top layer of dielectric material above the planarized top surface, creating a layer of liner material above the top dielectric layer, creating a top contact opening to the bottom contact, lining the top contact opening with a liner material, removing the liner at a bottom of the top contact opening, exposing the bottom contact, while preserving a portion of the liner on the top dielectric layer sufficient to allow adhesion of a subsequent conductive material, and filling the contact opening with the conductive material.

In one example, the layer of liner material above the top dielectric layer may have, for example, a thickness of about 10 nm to about 30 nm to satisfy the preserving aspect. In another example, the filling may create, for example, excess conductive material above the layer of liner material, and the method may further include, for example, planarizing the excess conductive material and the layer of liner material.

The method of the first aspect may further include, for example, creating a layer of sacrificial material over the layer of liner material prior to creating the top contact opening, the layer of sacrificial material satisfying the preserving aspect, and removing the sacrificial layer prior to filling the contact opening.

In one example, removing the sacrificial layer may be accomplished, for example, by removing the bottom liner. In another example, removing the sacrificial layer may include, for example, using a wet etch selective to the sacrificial layer.

The method of the first aspect may further include, for example, creating a layer of conductive material over the layer of liner material prior to creating the top contact opening, the layer of conductive material satisfying the preserving aspect.

In one example, the method of the first aspect may further include, for example, leaving a remainder of the conductive layer intact prior to filling the top contact. In another example, the conductive material of the bottom contact and the layer of conductive material may include, for example, a same conductive material.

In a second aspect, disclosed above is a semiconductor structure. The structure includes a lined bottom contact filled with conductive material. The structure further includes a layer of dielectric material surrounding sides of the lined bottom contact, a top contact on the bottom contact, the top contact having a partial liner only along sides thereof with an absence of the liner at a bottom thereof and being filled with the conductive material, and a layer of the dielectric material surrounding sides of the partially lined top contact.

In one example, the conductive material may include, for example, tungsten, the liner material may include, for example, a metal, and the metal may include, for example, titanium nitride, and the dielectric material may include, for example, an oxide inter-layer dielectric.

The semiconductor structure of the second aspect may further include, for example, raised semiconductor structure(s) coupled to the semiconductor substrate, the source region(s) and drain region(s) being situated in the raised structure(s).

The semiconductor structure of the second aspect may be part of, for example, a source and/or drain, or, as another example, may take the form of a local interconnect.

In a third aspect, disclosed above is a semiconductor structure. The structure includes at least one lined bottom contact filled with a conductive material and surrounded by a layer of dielectric material. The structure further includes another layer of dielectric material over the region(s) and the layer of dielectric material, a layer of contact liner material over the another layer of dielectric material, and a preserving layer above the layer of contact liner material, the preserving layer preserving the layer of contact liner material in subsequent processing.

In one example, the structure of the third aspect may be, for example, silicon-based, and the preserving layer may include, for example, a sacrificial layer of a silicon-based material.

In one example, the sacrificial layer may include, for example, one of amorphous silicon, silicon nitride and silicon dioxide.

In one example, the preserving layer in the structure of the third aspect may include, for example, a layer of conductive material. In another example, where the preserving layer includes a layer of conductive material, the preserving layer may include, for example, tungsten.

In one example, the semiconductor structure of the third aspect may be, for example, situated in a raised semiconductor structure coupled to a semiconductor substrate.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting structure, the structure comprising a lined bottom contact filled with conductive material, being surrounded by a layer of dielectric material and having a planarized top surface;
creating a top layer of dielectric material above the planarized top surface;
creating a layer of liner material above the top dielectric layer;
creating a top contact opening to the bottom contact;
lining the top contact opening with a liner material;
removing the liner at a bottom of the top contact opening, exposing the bottom contact, while preserving a portion of the liner on the top dielectric layer sufficient to allow adhesion of a subsequent conductive material; and
filling the contact opening with the conductive material.

2. The method of claim 1, wherein the layer of liner material above the top dielectric layer has a thickness of about 10 nm to about 30 nm to satisfy the preserving.

3. The method of claim 1, wherein the filling creates excess conductive material above the layer of liner material, the method further comprising planarizing the excess conductive material and the layer of liner material.

4. The method of claim 1, further comprising:
creating a layer of sacrificial material over the layer of liner material prior to creating the top contact opening, the layer of sacrificial material satisfying the preserving; and
removing the sacrificial layer prior to filling the contact opening.

5. The method of claim 4, wherein removing the sacrificial layer is accomplished by removing the bottom liner.

6. The method of claim 4, wherein removing the sacrificial layer comprises using a wet etch selective to the sacrificial layer.

7. The method of claim 1, further comprising creating a layer of conductive material over the layer of liner material prior to creating the top contact opening, the layer of conductive material satisfying the preserving.

8. The method of claim 7, further comprising leaving a remainder of the conductive layer intact prior to the filling.

9. The method of claim 8, wherein the conductive material of the bottom contact and the layer of conductive material comprise a same conductive material.

10. A semiconductor structure, comprising:
at least one lined bottom contact filled with conductive material;
a layer of dielectric material surrounding sides of the lined bottom contact;
a top contact on the bottom contact, the top contact having a partial liner only along sides thereof with an absence of the liner at a bottom thereof and being filled with the conductive material; and
a layer of the dielectric material surrounding sides of the partially lined top contact.

11. The semiconductor structure of claim 10, wherein the conductive material comprises tungsten, wherein the liner material comprises a metal, and wherein the dielectric material comprises an oxide inter-layer dielectric.

12. The semiconductor structure of claim 11, wherein the liner comprises titanium nitride.

13. The semiconductor structure of claim 10, further comprising at least one raised semiconductor structure coupled to the semiconductor substrate, the at least one lined bottom contact being situated in the at least one raised structure.

14. The semiconductor structure of claim 10, wherein the semiconductor structure is part of at least one of a source, a drain and a local interconnect.

15. A semiconductor structure, comprising:
at least one lined bottom contact filled with a conductive material and surrounded by a layer of dielectric material;
another layer of dielectric material over the at least one region and the layer of dielectric material;
a layer of contact liner material over the another layer of dielectric material; and
a preserving layer above the layer of contact liner material, the preserving layer preserving the layer of contact liner material in subsequent processing.

16. The semiconductor structure of claim 15, wherein the structure is silicon-based, and wherein the preserving layer comprises a sacrificial layer of a silicon-based material.

17. The semiconductor structure of claim 16, wherein the sacrificial layer comprises one of amorphous silicon, silicon nitride and silicon dioxide.

18. The semiconductor structure of claim 15, wherein the preserving layer comprises a layer of conductive material.

19. The semiconductor structure of claim 18, wherein the preserving layer comprises tungsten.

20. The semiconductor structure of claim 15, wherein the semiconductor structure is situated in a raised semiconductor structure coupled to a semiconductor substrate.
